(19) United States
(12) Patent Application Publication
(10) Pub. No.: US 2017/0288417 A1
(43) Pub. Date: Oct. 5, 2017

(54) Fast Charging Apparatus and Method

(71) Applicant: Active-Semi (BVI) Inc., Allen, TX (US)

(72) Inventor: Narasimhan Trichy, Plano, TX (US)

(21) Appl. No.: 15/474,984

(22) Filed: Mar. 30, 2017

Related U.S. Application Data
(60) Provisional application No. 62/316,221, filed on Mar. 31, 2016.

(51) Int. Cl. H02J 7/00; G01R 31/36

(52) U.S. Cl. CPC H02J 7/007; G01R 31/3624

(57) ABSTRACT

A method comprises setting a first termination voltage, a first charging current and a first termination current in a first charging step, wherein the first termination current is a fraction of the first charging current, passing a current from a power source to a battery through a charger, wherein the charger operates in a first constant current mode and the current is equal to the first charging current, monitoring a voltage across two terminals of the battery and configuring the charger to operate in a first constant voltage mode when the voltage across the two terminals of the battery is equal to the first termination voltage and monitoring the current in the first constant voltage mode and configuring the charger to operate in a second charging step when the current is equal to the first termination current.

### CROSS REFERENCE TO RELATED APPLICATIONS

This application is related to, and claims priority to, U.S. Provisional Application No. 62/316,221, titled, “Fast Charging Apparatus and Method” filed on Mar. 31, 2016, which is herein incorporated by reference.

### TECHNICAL FIELD

The present invention relates to a battery charging control scheme, and, in particular embodiments, to a method for achieving fast charging in a battery charger system.

### Background

As technologies further advance, a variety of battery powered portable devices, such as mobile phones, tablet PCs, digital cameras, MP3 players and/or the like, have become popular. Each portable device may employ a plurality of rechargeable battery cells. The plurality of rechargeable battery cells may be connected in series or in parallel so as to form a rechargeable battery pack for storing electrical energy.

According to different combinations of electrode materials and electrolytes used in rechargeable batteries, rechargeable batteries may be divided into a variety of categories. The most common rechargeable batteries include nickel-cadmium (NiCd) batteries, nickel-metal hydride (NiMH) batteries, lithium-ion batteries, lithium-ion polymer batteries, lithium-air batteries, lithium iron phosphate batteries and the like.

Battery chargers are employed to restore energy to the batteries. The battery charger is controlled to provide voltage (e.g., a constant voltage charging mode) and current (e.g., a constant current charging mode) to the battery so as to restore energy to the battery. Depending on different applications and design needs, the charging speed as well as the amount of power applied to the battery may vary.

As power consumption has become more important, there may be a need for reducing the length of time to charge the battery. However, fast charging may cause a complex charging control scheme. The complexity of achieving fast charging has become a significant issue, which presents challenges to designers of battery charger systems.

### SUMMARY

In particular embodiments, a simple control scheme may achieve fast charging and improve the performance of a battery charger system.

In accordance with an embodiment, a method comprises setting a first termination voltage, a first charging current and a first termination current in a first charging step, wherein the first termination current is a fraction of the first charging current, passing a current from a power source to a battery through a charger, wherein the charger operates in a first constant current mode and the current is equal to the first charging current, monitoring a voltage across two terminals of the battery and configuring the charger to operate in a first constant voltage mode when the voltage across the two terminals of the battery is equal to the first termination voltage and monitoring the current in the first constant voltage mode and configuring the charger to operate in a second charging step when the current is equal to the first termination current.

In accordance with another embodiment, a method comprises applying a first constant current mode to a battery through a charger, in the first constant current mode, monitoring a voltage across two terminals of the battery and configuring the charger to operate in a first constant voltage mode when the voltage across the two terminals of the battery is equal to a first termination voltage, in the first constant voltage mode, monitoring a current flowing through the battery and configuring the charger to operate in a second constant current mode when the current flowing through the battery is equal to a first termination current, wherein the first termination current is a fraction of the current flowing through the battery in the first constant current mode, in the second constant current mode, monitoring the voltage across two terminals of the battery and configuring the charger to operate in a second constant voltage mode when the voltage across the two terminals of the battery is equal to a second termination voltage and in the second constant voltage mode, monitoring the current flowing through the battery and configuring the charger to operate in a third constant current mode when the current flowing through the battery is equal to a second termination current, wherein the second termination current is a fraction of the current flowing through the battery in the second constant current mode.

In accordance with yet another embodiment, an apparatus comprises a charger configured to apply a charge current to a battery and a controller configured to monitor a voltage across two terminals of the battery and a current flowing through the battery, wherein, based on the voltage across two terminals of the battery and the current flowing through the battery, the controller configures the charger to operate in a plurality of constant current modes and a plurality of constant voltage modes, and wherein the plurality of constant current modes and the plurality of constant voltage modes are applied to the charger consecutively, and wherein the plurality of constant current modes and the plurality of constant voltage modes form a plurality of charging steps, each charging step comprising four parameters including a termination voltage, a charge current, a termination current and a time-out, and wherein a behavior of each charging step is determined by the four parameters.

An advantage of a preferred embodiment of the present invention is improving a battery charger system's performance through a multi-step fast charging control mechanism.

The foregoing has outlined rather broadly the features and technical advantages of the present invention in order that the detailed description of the invention that follows may be better understood. Additional features and advantages of the invention will be described hereinafter which form the subject of the claims of the invention. It should be appreciated by those skilled in the art that the conception and specific embodiment disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 illustrates a block diagram of a battery charger system in accordance with various embodiments of the present disclosure;

FIG. 2 is a charge rate chart illustrating the operating principle of the battery charger system shown in FIG. 1 in accordance with various embodiments of the present disclosure;

FIGS. 3-4 illustrate a flow chart of a method for controlling the charging of the battery charger system shown in FIG. 1 in accordance with various embodiments of the present application; and

FIG. 5 is another charge rate chart illustrating the operating principle of the battery charger system shown in FIG. 1 in accordance with various embodiments of the present disclosure.

Corresponding numerals and symbols in the different figures generally refer to corresponding parts unless otherwise indicated. The figures are drawn to clearly illustrate the relevant aspects of the various embodiments and are not necessarily drawn to scale.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

The present invention will be described with respect to preferred embodiments in a specific context, namely a fast charging apparatus for a battery charger system. The invention may also be applied, however, to a variety of systems including a single battery cell, a plurality of battery cells connected in series, a plurality of battery cells connected in parallel, any combinations thereof and the like. Hereinafter, various embodiments will be explained in detail with reference to the accompanying drawings.

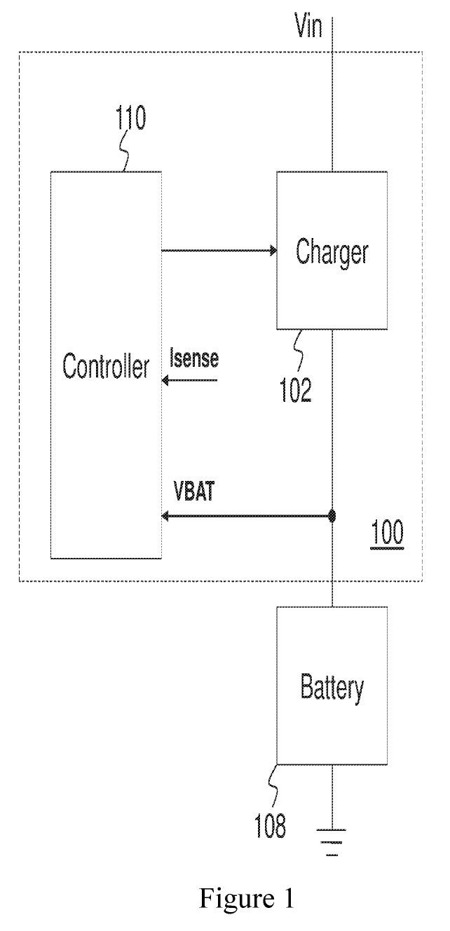

FIG. 1 illustrates a block diagram of a battery charger system in accordance with various embodiments of the present disclosure. The battery charger system 100 is coupled between a power source Vin and a battery 108. The power source Vin may be a power adapter converting a utility line voltage to a dc voltage. Alternatively, the power source Vin may be a renewable power source such as a solar panel array. Furthermore, the power source Vin may be an energy storage device such as rechargeable batteries, fuel cells and/or the like.

The battery 108 may be a nickel-cadmium (NiCd) battery, a nickel-metal hydride (NiMH) battery, a lithium-ion battery, a lithium-ion polymer battery, a lithium-air battery, a lithium iron phosphate battery and the like. In some embodiments, the battery 108 may comprise a single cell. In alternative embodiments, the battery 108 may comprise a plurality of rechargeable battery cells connected either in series or in parallel.

It should be noted that while FIG. 1 illustrates a battery charger system, one having ordinary skill in the art would recognize that the battery charger system in FIG. 1 is merely an example and is not meant to limit the current embodiments.

The battery charger system 100 comprises a battery charger 102 and a controller 110. The battery charger 102 is connected between the power source Vin and the battery 108. In some embodiments, the battery charger 102 provides a conductive path for charging the battery 108. In some embodiments, the battery charger 102 may be implemented as an isolated dc/dc converter, a non-isolated dc/dc converter, a linear regulator and the like.

In some embodiments, the controller 110 may be implemented as a digital controller comprising a plurality of registers. The digital controller may be implemented in hardware, software, any combinations thereof and the like. The controller 110 is employed to receive detected current (e.g., Isense) and voltage signals (e.g., VBAT) and adjust the charging process accordingly. More particularly, the detected current signal represents the current flowing through the battery 108. The detected current signal Isense can be obtained by using suitable current sensing apparatuses such as a sense resistor connected in series with the battery 108, a sense transistor connected in parallel with a main power switch of the battery charger 102, any combinations thereof and the like. The battery voltage VBAT can be directly measured across two terminals of the battery 108.

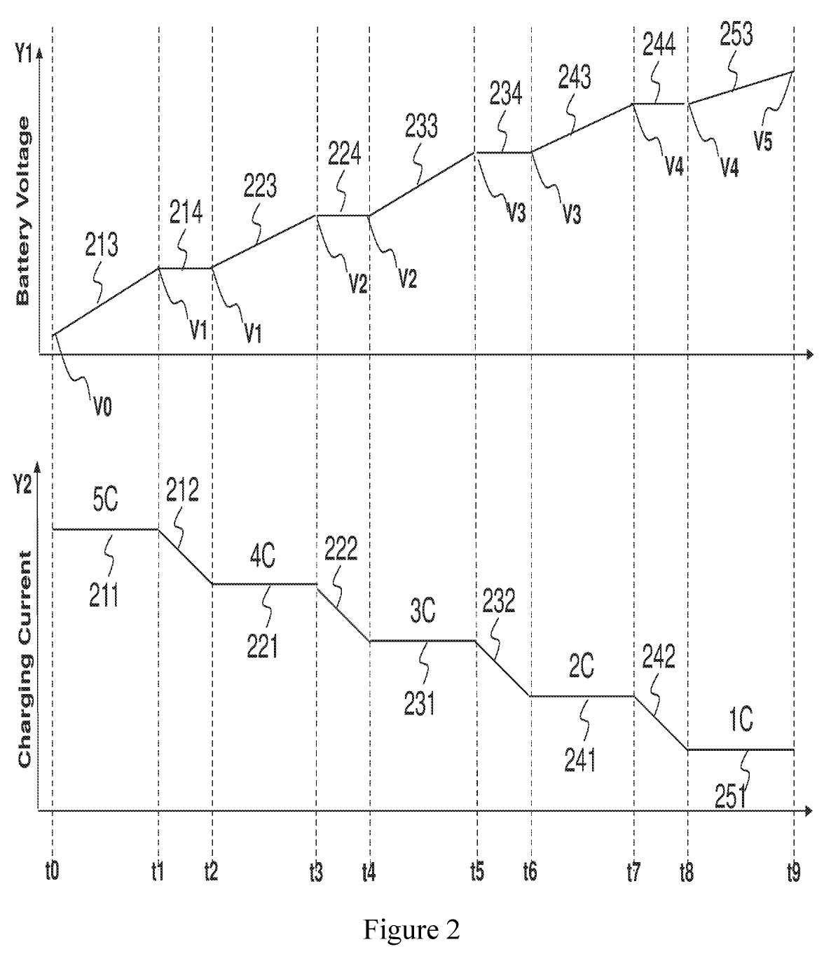

FIG. 2 is a battery charge rate chart illustrating the operating principle of the battery charger system shown in FIG. 1 in accordance with various embodiments of the present disclosure. There are two vertical axes. The first vertical axis Y1 represents the voltage across two terminals of the battery 108. The second vertical axis Y2 represents the battery charge current flowing through the batter 108. The horizontal axis of FIG. 2 represents the charge time of a five-step charging process.

According to some embodiments, a rate of 1C represents charging a battery with consumable capacity in one hour. The “C rate” defines the current needed to fully charge a battery with capacity C in one hour. For example, a 1C rate for a 2000 mAh battery is applying 2000 mA for one hour to fully charge the battery. As such, for the same battery, a 5C rate is applying 10 A for 12 minutes to fully charge the battery.

As shown in FIG. 2, the charge rate profile of the battery charger system 100 includes five portions, namely a first portion including a first straight line portion 211 and a first slope portion 212, a second portion including a second straight line portion 221 and a second slope portion 222, a third portion including a third straight line portion 231 and a third slope portion 232, a fourth portion including a fourth straight line portion 241 and a fourth slope portion 242 and a fifth portion including a fifth straight line portion 251.

The five portions shown in FIG. 2 represent five steps of a fast battery charging control scheme. Time instances t2, t4, t6 and t8 are transition time instances between different steps. In some embodiments, in order to achieve autonomous transitions between different charging steps shown in FIG. 2, five termination currents are selected. For example, a first termination current is a fraction of the charging current of the first charge step. As shown in FIG. 2, the charging current of the first charging step is of a 5C rate. The termination current of the first charging step is a user chosen value. For example, the termination current of the first charging step may be of a 4C rate. It should be noted while the example in FIG. 2 shows the termination current of the first charging step is equal to the charging current of the second charge step, a person skilled in the art would understand this is merely an example. Many variations are possible. For example, after a battery has been charged with a current higher than the 1C charge rate, the battery requires battery relaxation time where a lower charging current such as 0.5C charge rate is applied to the battery before the charger proceeds to the next fast charging step. Therefore, there may be an intermediate step between the first charging step and the second charging step. As such, the termination current of the first charging step may be not equal to the charge current of the second charging step.

In some embodiments, a second termination current of the second charging step (from t2 to t4 in FIG. 2) is of a 3C rate. A third termination current of the third charging step (from t4 to t6 in FIG. 2) is of a 2C rate. A fourth termination current of the fourth charging step (from t6 to t8 in FIG. 2) is of a 1C rate. A fifth termination current of the fifth charging step (from t8 to t9 shown in FIG. 2) is a fraction of the charge current in the fifth charging step.

It should be noted that the chart shown in FIG. 2 is merely an example, which should not unduly limit the scope of the claims. One of ordinary skill in the art would recognize many variations, alternatives, and modifications. For example, depending on different applications and design needs, the charge currents and the termination currents described above may vary. Furthermore, FIG. 2 illustrates only five steps of the fast charging control scheme that may include hundreds of such steps. The number of steps illustrated herein is limited solely for the purpose of clearly illustrating the inventive aspects of the various embodiments. The present invention is not limited to any specific number of charging steps.

In some embodiments, a battery's voltage may drop to an unduly low output voltage after the battery has been over-discharged. The over-discharged battery may have an internal short circuit. Prior to applying fast charging to the over-discharged battery, a weak charging current is supplied to the battery until the output voltage of the battery reaches a predetermined voltage (e.g., V0 shown in FIG. 2) such as 3.2 V.

Referring back to FIG. 2, at t0, the battery 108 has been pre-charged to a suitable voltage V0 such as 3.2 V. Then, a fast charge control scheme is applied to the battery charger system 100 so that the battery reaches its fully charged voltage V5 such as 4.4 V in five charge steps.

From t0 to t1, the charger operates in a constant current mode with a 5C charge rate. In response to the constant current mode, the battery voltage increases in a linear manner as indicated by a first upward slope 213. After the battery voltage reaches a first termination voltage V1, the charger system enters a constant voltage mode at t1 and stays at the constant voltage mode until t2 as indicated by a first straight line 214. In response to the constant voltage mode, the charge current drops in a linear manner as indicated by the first downward slope line 212. When the charge current reaches the termination current of the first charging step (4C as shown in FIG. 2), the controller detects this and changes the operating mode to a constant current mode at t2 with a 4C charge rate.

It should be noted that the transition described above can be achieved through a scaled approach. For example, when the charger system operates with the 5C charge rate, the scaling factor may be set as 80%. The battery charger system charges the battery with the 5C charge rate and enters the constant voltage mode and waits for the charge current to drop to 80% of 5C, which is equal to 4C. In other words, when the current flowing through the battery drops to 80% of 5C, a new constant current mode (e.g., 4C charge rate) is applied to the battery charger system. Furthermore, in the second charging step, the controller sets a second termination voltage (e.g., V2 shown in FIG. 2), a second termination current and a second charging current.

One advantageous feature of having the scaled approach is that it is not necessary for the battery charger system to look at the next step of 4C charge since the scale factor of 80% has been internally set. The next step of 4C can be calculated based upon the first step of 5C and the scaled factor of 80%. This principle can be applicable all steps and transitions between different steps shown in FIG. 2.

From t2 to t3, the charger operates in the constant current mode with the 4C charge rate. In response to the constant current mode, the battery voltage increases in a linear manner as indicated by a second upward slope 223. After the battery voltage reaches the second termination voltage V2, the charger system enters a constant voltage mode at t3 and stays at the constant voltage mode until t4 as indicated by a second straight line 224. In response to the constant voltage mode starting from t3, the charge current drops in a linear manner as indicated by the second downward slope line 222. When the charge current reaches the second termination current of the second charging step (e.g., 3C as shown in FIG. 2), the controller detects this and changes the operating mode to a constant current mode at t4 with a 3C charge rate. Also at t4, the charger enters the third charging step in which the controller sets a third termination voltage (e.g., V3 shown in FIG. 2), a third termination current and a third charging current.

From t4 to t5, the charger operates in the constant current mode with the 3C charge rate. In response to the constant current mode, the battery voltage increases in a linear manner as indicated by a third upward slope 233. After the battery voltage reaches the third termination voltage V3, the charger system enters a constant voltage mode at t5 and stays at the constant voltage mode until t6 as indicated by a third straight line 234. In response to the constant voltage mode starting from t5, the charge current drops in a linear manner as indicated by the third downward slope line 232. When the charge current reaches the third termination current of the third charging step (e.g., 2C as shown in FIG. 2), the controller detects this and changes the operating mode to a constant current mode at t6 with a 2C charge rate. Also at t6, the charger enters the fourth charging step in which the controller sets a fourth termination voltage (e.g., V4 shown in FIG. 2), a fourth termination current and a fourth charging current.

From t6 to t7, the charger operates in the constant current mode with the 2C charge rate. In response to the constant current mode, the battery voltage increases in a linear manner as indicated by a fourth upward slope 243. After the battery voltage reaches the fourth termination voltage V4, the charger system enters a constant voltage mode at t7 and stays at the constant voltage mode until t8 as indicated by a fourth straight line 244. In response to the constant voltage mode starting from t7, the charge current drops in a linear manner as indicated by the fourth downward slope line 242. When the charge current reaches the fourth termination current of the fourth charging step (e.g., 1C as shown in FIG. 2), the controller detects this and changes the operating mode to a constant current mode at t8 with a 1C charge rate. Also at t8, the charger enters the fifth charging step in which the controller sets a fifth termination voltage (e.g., V5 shown in FIG. 2), a fifth termination current and a fifth charging current.

From t8 to t9, the charger operates in the constant current mode with the 1C charge rate until the battery reaches its full capacity. In response to the constant current mode, the battery voltage increases in a linear manner as indicated by a fifth upward slope 253.

During the five-step charging process described above, the battery charge system automatically enters a new operating mode. This results in the fastest charge time possible because this control scheme does not require looking ahead to the next step and knowing the next charge setting. This simplifies the state machine of the controller 110 and makes the state machine more stable and easy to implement. Such an autonomous transition helps to improve the charge speed. As a result, the battery charger system may achieve fast charging.

Additionally, the fast charging control scheme shown in FIG. 2 allows easy conversion of a single step charger (e.g., a conventional charger) to an autonomous fast charger with multiple charge current settings through the battery charge voltage range with simple modification to the charging state machine. In particular, the simple modification is much quicker to implement because it only involves a digital change without changing anything in the analog portion of the charger. Such simple modification helps to improve the time-to-market for products and shorten the time for designing battery chargers.

It should be noted that the charging steps, the termination voltages, the charging currents and the termination currents in FIG. 2 are merely an example. A person skilled in the art would understand there may be many alternatives, modifications and variations. For example, more charging steps may be added with simple addition of termination voltage, charge current and fraction of charge current to detect termination current in the same step before transitioning to the next register set that captures the next termination voltage, charge current and termination current. So the solution is easily scalable to multiple steps.

Furthermore, the five-step charging process shown in FIG. 2 can be modified based upon the chemical characteristics of batteries. For example, battery chemistries allow higher than 1C charge. For example, 2C charge may be allowed, but only in a specific voltage range such as from 3.6 V-3.8 V. By using the control scheme of the five-step charging process shown in FIG. 2, knowing the maximum charge currents are allowed in specific battery voltage ranges, a fastest charge process can be achieved by breaking down the charging process into a piecewise linear function based on battery voltages and their respective allowed currents. Each portion of the piecewise linear function is treated as one step of a multi-step charging process. Based upon the battery voltage and the allowed current of each portion of the piecewise linear function, corresponding termination voltages, termination currents and charging currents can be set accordingly.

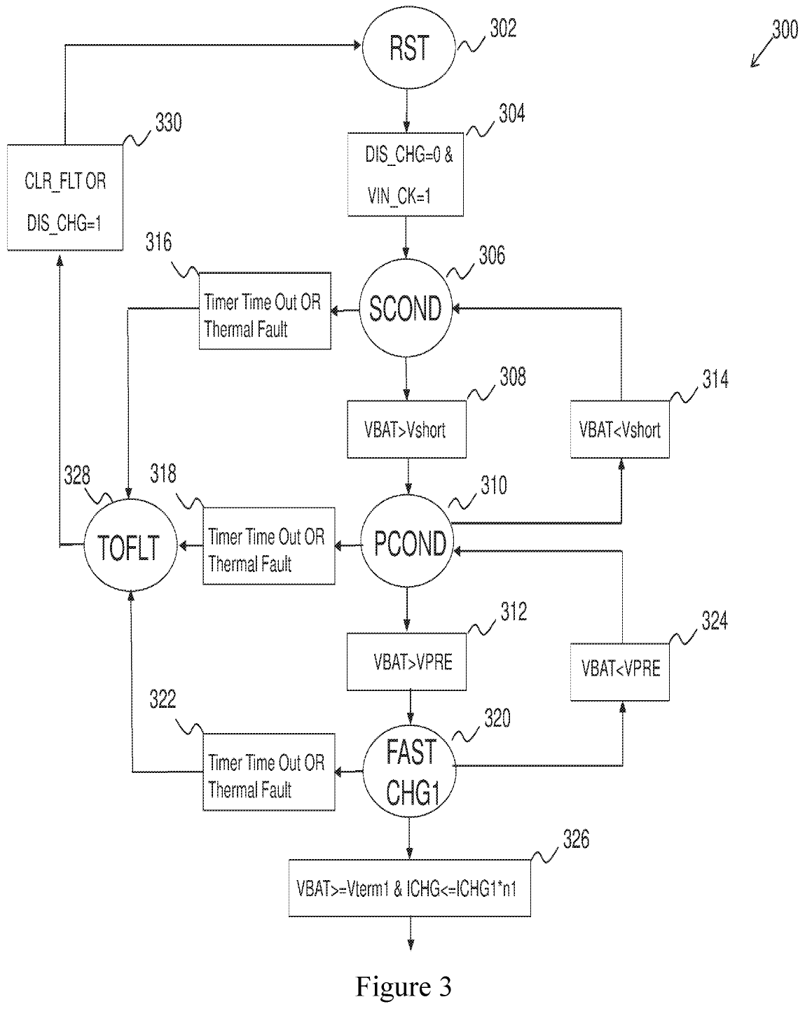

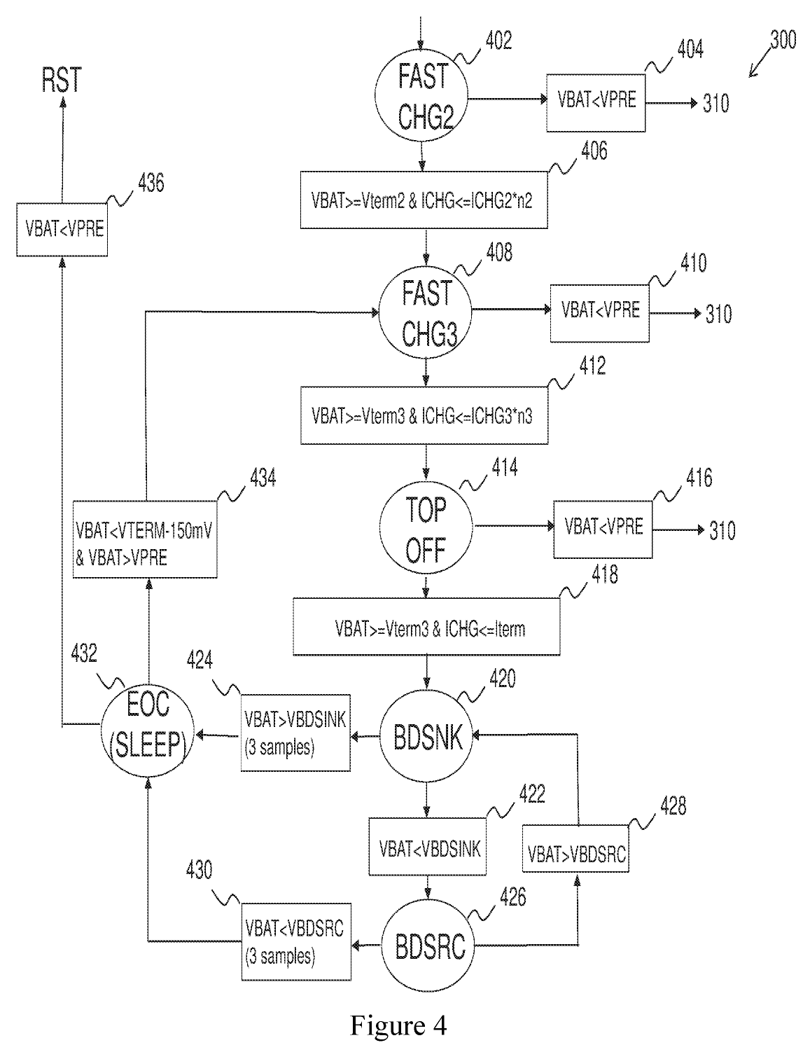

FIGS. 3-4 illustrate a flow chart of a method 300 for controlling the charging of the battery charger system 100 shown in FIG. 1 in accordance with various embodiments of the present application. This flowchart shown in FIGS. 3-4 is merely an example, which should not unduly limit the scope of the claims. One of ordinary skill in the art would recognize many variations, alternatives, and modifications. For example, various steps as illustrated in FIGS. 3-4 may be added, removed, replaced, rearranged and repeated.

The method 300 starts at step 302 where the controller resets a plurality of registers. For example, various fault flags in the register unit of the controller are reset. At step 304, the controller determines whether abnormal situations have occurred. For example, an input under voltage lock out (UVLO) occurs when variable VIN_CK is set to LOW (=0). On the other hand, an excessive discharge current flowing through the battery occurs when variable DIS_CHG is set to high (=1). At step 304, if the abnormal situations have not occurred, the method 300 proceeds to step 306.

At step 306, the controller determines whether the battery is in a short circuit mode. In some embodiments, a short circuit threshold voltage is in a range from about 2.4 V to about 2.5 V. If the battery voltage is less than 2.5 V, the battery is in the short circuit mode and the controller charges the battery slowly with a first charging current until the battery voltage reaches a first predetermined threshold. In some embodiments, the first predetermined threshold is about 2.5 V. The first charging current is about 25 mA.

At step 308, if the battery voltage exceeds the first predetermined threshold (e.g., 2.5 V), the method 300 proceeds to step 310. At step 310, the controller first determines whether the battery is in a pre-charge mode. In some embodiments, the battery is in the pre-charge mode if the battery voltage is in a range from about 2.5 V to about 3.2 V.

Also at step 310, if the battery voltage is less than 3.2 V, the battery is in the pre-charge mode and the controller charges the battery with a second charging current until the battery voltage reaches a second predetermined threshold. In some embodiments, the second predetermined threshold is about 3.2 V. The second charging current is in a range from about 25 mA to about 200 mA. Also at step 310, the controller keeps detecting the battery voltage. If the battery voltage is less than the first predetermined threshold (e.g., 2.5 V), the method 300 returns to step 306 through step 314 as shown in FIG. 3.

At step 312, the controller determines whether the battery comes out of the pre-charge mode. If the battery voltage exceeds the second predetermined threshold (e.g., 3.2 V), the method 300 proceeds to step 320. Throughout the description, the second predetermined threshold is alternatively referred to as the pre-charge threshold.

The method shown in FIGS. 3-4 is based upon a three-step fast charging process. In the flowchart shown in FIGS. 3-4, steps 320, 402 and 408 represent a first charging step, a second charging step and a third charging step, respectively. In order to have autonomous transitions between different charging steps, in each step of the fast charge process, the controller sets a termination voltage, a charging current and a termination current, which is a fraction of the charging current. For example, in the first charging step, a first termination voltage is 3.8 V and a first charging current is a 3C charge rate. A first termination current is a user chosen value, which is a fraction of the first charging current. In the second charging step, a second termination voltage is 4.2 V and the second charging current is a 2C charge rate. A second termination current is a user chosen value, which is a fraction of the second charging current. In the third charging step, a third termination voltage is 4.4 V and a third charging current is a 1C charge rate. A third termination current is a user chosen value, which is a fraction of the third charging current.

It should be noted that the vales of the termination voltages (e.g., 3.8 V) and the charge rates of the charging currents (e.g., 3C charge rate) are merely examples. A person skilled in the art would understand other suitable values and charge rates may be used depending on different applications and design needs.

Referring back to FIG. 3, at step 320, the battery enters the first charging step including two different modes. A first constant current mode with a 3C charge rate is applied to the battery and the battery voltage increase from about 3.2 V to about 3.8 V. At step 326, after the battery voltage reaches the first termination voltage (e.g., 3.8 V), the controller applies a first constant voltage mode to the battery, and the battery voltage stays at the first termination voltage. In the first constant voltage mode, the charging current drops accordingly.

Also at step 326, after the charging current is less than or equal to a fraction (n1) of the current of the first constant charging mode (ICHG1), the controller changes the charger's operation mode from the first constant voltage mode to a second constant current mode having a charge current. After that, the method 300 proceeds to step 402.

It should be noted that n1 is a user chosen number in a range from 0 to 1. Depending on different applications and design needs, n1 may vary accordingly.

At step 402, the battery enters the second charging step. In the second charging step, the second constant current mode with the 2C charge rate is applied to the battery and the battery voltage increase from about 3.8 V to about 4.2 V. At step 406, after the battery voltage reaches 4.2 V, the controller applies a second constant voltage mode to the battery, and the battery voltage stays at 4.2 V. In the second constant voltage mode, the charging current drops accordingly.

Also at step 406, after the charging current is less than or equal to a fraction (n2) of the current of the second constant charging mode (ICHG2), the controller changes the charger's operation mode from the second constant voltage mode to a third constant current mode. After that, the method 300 proceeds to step 408.

It should be noted that n2 is a user chosen number in a range from 0 to 1. Depending on different applications and design needs, n2 may vary accordingly.

At step 408, the battery enters the third charging step. In the third charging step, the third constant current mode with the 1C charge rate is applied to the battery and the battery voltage increase from about 4.2 V to about 4.4 V. At step 412, after the battery voltage reaches 4.4 V, the controller applies a third constant voltage mode to the battery, and the battery voltage stays at 4.4 V. In the third constant voltage mode, the charging current drops accordingly. Also at step 412, after the charging current is less than or equal to a fraction (n3) of the current of the third constant charging mode (ICHG3), the method 300 proceeds to step 414.

It should be noted that n3 is a user chosen number in a range from 0 to 1. Depending on different applications and design needs, n3 may vary accordingly.

The termination voltage, the charging current and the termination current (represented by a fraction) of each charging step can be saved in a user programmable control register of the controller. In a conventional one-step charger, three registers may be used to set the termination voltage, the charging current and the termination current. This conventional one-step charger can function as a multi-step charger by using a multiplexer to change the settings of these three registers at the correct time. As a result, a multi-step charger can be obtained by applying simple digital changes to the three registers of the conventional one-step charger.

At step 414, the battery operates in the third constant voltage mode. At step 418, if the battery voltage is greater than or equal to the third termination voltage (e.g., 4.4 V) and the current flowing through the battery is less than or equal to a predetermined termination current, the method 300 proceeds to a battery capacity testing phase including steps 420, 422, 424, 426, 428 and 430 shown in FIG. 4.

At step 420, a predetermined sink current is applied to the battery for about 250 milliseconds. In some embodiments, the predetermined sink current is about 2.5 mA. At step 422, if the battery voltage is less than a predetermined battery sink voltage threshold, the method 300 proceeds to step 426. On the other hand, after applying the sink current to the battery, if the battery voltage is greater than the predetermined battery sink voltage threshold for three consecutive samples, the battery is fully charged and the method 300 proceeds to step 432 where the battery is isolated from the charger.

At step 426, a predetermined source current is applied to the battery for about 250 milliseconds. In some embodiments, the predetermined sink current is about 25 mA. At step 428, if the battery voltage is greater than a predetermined battery source voltage threshold, the method 300 return to step 420 from step 426. On the other hand, after applying the source current to the battery, if the battery voltage is less than the predetermined battery source voltage threshold for three consecutive samples, the battery is fully charged and the method 300 proceeds to step 432 where the battery is isolated from the charger.

At step 432, the output voltage of the charger is regulated at a voltage slightly higher than the fully charged voltage of the battery. For example, the fully charged voltage of the battery is 4.4 V. At step 432, the output voltage of the charger is in a range from about 4.55 V to about 4.6 V.

The method 300 includes a variety of protection steps. As shown in FIG. 3, when the battery is in steps 306, 310 and 320 and abnormal situations occur, the method 300 may disable the charging currents and proceed to a protection step 328 through steps 316, 318 and 322, respectively. At step 328, a variety of fault flags are set. The method 300 may return to step 302 from step 328 through step 330 where a variety of register units are set in response to the abnormal situations. The abnormal situations comprise a timer time out, a thermal fault and/or the like.

Furthermore, in order to protect the battery during the fast charging process, the battery may return to the pre-charge mode when the battery voltage is less than the pre-charge threshold. For example, at step 324, if the battery voltage is less than the pre-charge threshold, the method 300 leaves the first charging step and returns to the pre-charge mode at step 310. Likewise, at step 404, if the battery voltage is less than the pre-charge threshold, the method 300 leaves the second charging step and returns to the pre-charge mode at step 310. At step 410, if the battery voltage is less than the pre-charge threshold, the method 300 leaves the third charging step and returns to the pre-charge mode at step 310. At step 416, if the battery voltage is less than the pre-charge threshold, the method 300 leaves step 414 and returns to the pre-charge mode at step 310.

Additionally, after the battery is fully charged and the method 300 stays at step 432, a voltage fluctuation at the battery may cause the charger to leave the fully charged mode. For example, at step 434, if the battery voltage is about 150 mV less than the fully charged voltage, but is greater than the pre-charge threshold, the method 300 leaves the fully charged mode and returns to step 408. Likewise, at step 436, if the battery voltage is less than the pre-charge threshold, the method 300 leaves the fully charged mode and returns to step 302.

One advantageous feature of having the method 300 shown in FIGS. 3-4 is that the three-step fast charging process can be accomplished without firmware intervention and completed autonomously by providing access to user programmable registers that control the settings of termination voltages, termination currents and charge currents. FIGS. 3-4 only illustrate a three-step fast charging process. The method described above can be extended to multiple steps.

Another advantageous feature of having the method 300 shown in FIGS. 3-4 is that a charger controlled by the method 300 can achieve a fully autonomous charging. For example, once the battery type is determined and characterized, the methodology shown in FIGS. 3-4 is very convenient to implement a fully autonomous charging. This takes the burden off of a controller that may be needed to track battery voltage and change the charge rates at appropriate time. While other fast charging methods may need inputs from a charge algorithm, this implementation shown in FIGS. 3-4 can autonomously charge once the termination voltage, termination current and charging current of a step are programmed in three registers. The ability to be autonomous during a fast charging process helps to improve the performance of a charger system.

In FIGS. 3-4, each charging step includes three parameters, namely a termination voltage, a charging current and a termination current. According to the description above with respect to FIGS. 3-4, the charger leaves the present charging step and enters a new charging step when the current flowing through the battery is equal to the termination current of the present charging step. In some embodiments, each charging step may include a time-out parameter (a user chosen timer). At the beginning of each charging step, all four parameters are set. In a charging step, if a time-out event occurs before the current reaches the termination current, the time-out parameter overrides the termination current parameter. The charger enters a new charging step immediately after the time-out event occurs.

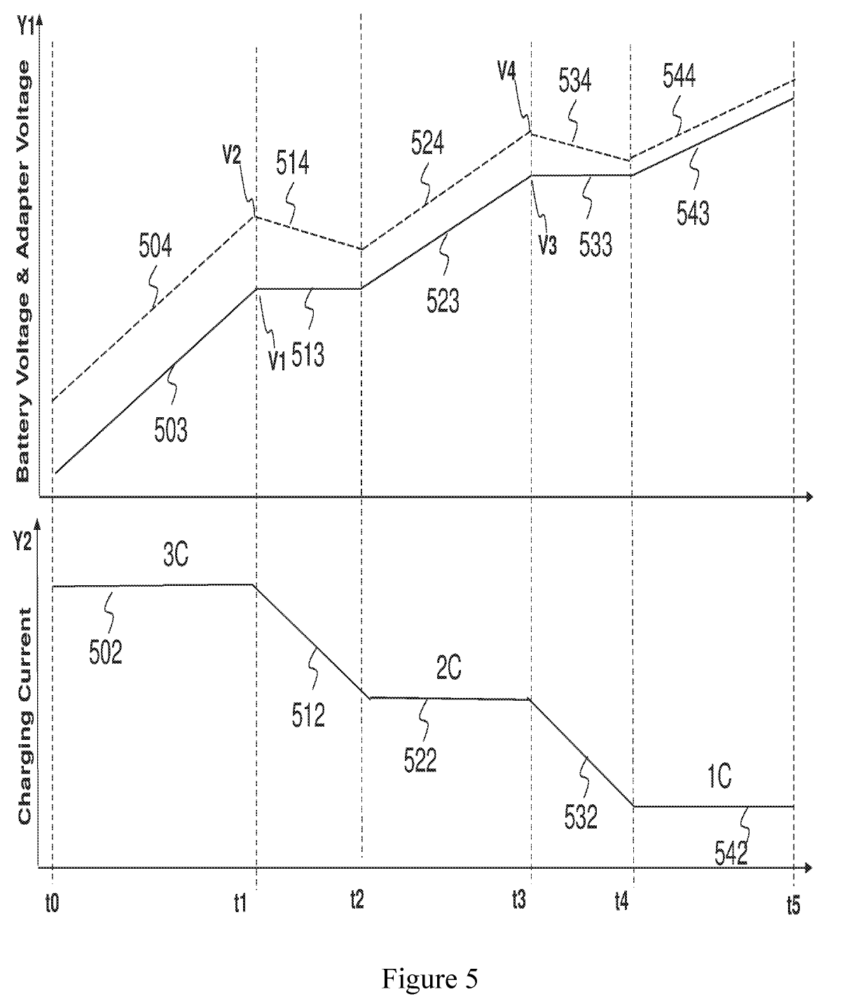

FIG. 5 is another charge rate chart illustrating the operating principle of the battery charger system shown in FIG. 1 in accordance with various embodiments of the present disclosure. The charge rate chart shown in FIG. 5 is similar to that shown in FIG. 2 except that the battery is charged through a three-step charging process. A first charging step includes a first constant current mode (represented by line 502) and a first constant voltage mode (represented by line 512). A second charging step includes a second constant current mode (represented by line 522) and a second constant voltage mode (represented by line 532). A third charging step includes a third constant current mode (represented by line 542).

The autonomous transition between different steps (e.g., from a 3C charge rate to a 2C charge rate) has been described above with respect to FIG. 2, and hence is not discussed again to avoid unnecessary repetition.

FIG. 5 further illustrates a charging control scheme considering the internal resistance (IR) drop of the battery. The dashed lines 504, 514, 524, 534 and 544 represent an output voltage of the charger. The lines 503, 513, 523, 533 and 543 represent the actual battery voltage. In some embodiments, various resistive elements may be placed between the output of the charger and the battery. For example, the resistive elements include trace resistance, battery connector resistance, battery protection switch resistance and battery internal resistance and the like.

In order to compensate the voltage drop caused by the various resistive elements, a current dependent compensation factor has been added into the output voltage of the charger. For example, in a first constant voltage mode from t1 to t2, the current flowing through the battery drops in a linear manner as indicated by the line 512. In order to compensate the IR voltage drop caused by the current flowing through the battery, the output voltage of the charger drops in a similar manner as indicated by the dashed line 514. FIG. 5 shows the output voltage of the charger drops in a linear manner from V2 to V1.

Although embodiments of the present invention and its advantages have been described in detail, it should be understood that various changes, substitutions and alterations can be made herein without departing from the spirit and scope of the invention as defined by the appended claims.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A method comprising:
setting a first termination voltage, a first charging current and a first termination current in a first charging step, wherein the first termination current is a fraction of the first charging current;
passing a current from a power source to a battery through a charger, wherein the charger operates in a first constant current mode and the current is equal to the first charging current;
monitoring a voltage across two terminals of the battery and configuring the charger to operate in a first constant voltage mode when the voltage across the two terminals of the battery is equal to the first termination voltage; and
monitoring the current in the first constant voltage mode and configuring the charger to operate in a second charging step when the current is equal to the first termination current.

2. The method of claim 1, further comprising:
in the second charging step, setting a second termination voltage, a second charging current and a second termination current, wherein the second termination current is a fraction of the second charging current;
monitoring the voltage across two terminals of the battery and configuring the charger to operate in a second constant voltage mode when the voltage across the two terminals of the battery is equal to the second termination voltage; and
monitoring the current in the second constant voltage mode and configuring the charger to operate in a third charging step when the current in the second constant voltage mode is equal to the second termination current.

3. The method of claim 2, wherein:
setting the first termination voltage, the first charging current and the first termination current through a first digital change of three registers of a digital controller; and
setting the second termination voltage, the second charging current and the second termination current through a second digital change of the three registers of the digital controller.

4. The method of claim 3, wherein:
the first termination voltage is approximately equal to 3.8 V; and
the second termination voltage is approximately equal to 4.2 V.

5. The method of claim 3, wherein:
the first termination voltage, the first charging current and the first termination current are determined based upon chemical characteristics of the battery.

6. The method of claim 3, wherein:
in the first constant voltage mode, the voltage across the two terminals of the battery is equal to the first termination voltage; and
in the second constant voltage mode, the voltage across the two terminals of the battery is equal to the second termination voltage.

7. The method of claim 1, further comprising:
applying a pre-charge mode to the battery until the voltage across the two terminals of the battery reaches a pre-charge threshold wherein in the pre-charge mode, a current flowing through the battery is in a range from about 25 mA to about 200 mA.

8. The method of claim 1, further comprising:
providing a piecewise linear function representing a charging profile of the battery, wherein the piecewise linear function comprises a plurality of portions;
setting four parameters including the first termination voltage, the first charging current, the first termination current and a first time-out in a first charging step, wherein the first charging step corresponds to a first portion of the piecewise linear function;
repeating the step of setting the four parameters to build a plurality of subsequent charging steps, wherein each subsequent charging step corresponds to a portion of the piecewise linear function, and wherein a charge behavior of each charging step is determined in each charging step by the four parameters corresponding to that charging step; and
cascading the first charging step and the plurality of subsequent charging steps to form an entire charge profile, where the entire charge profile can be modified to suit a variety of batteries and their specific charge profiles for fast charging, and wherein the number of steps of the entire charge profile can be increased or decreased by adding or removing the setting of the four parameters for each step.

9. The method of claim 1, further comprising:
setting a time-out in the first charging step; and
configuring the charger to operate in the second charging step by overriding the first termination current when a time-out event occurs in the first charging step.

10. A method comprising:
applying a first constant current mode to a battery through a charger;
in the first constant current mode, monitoring a voltage across two terminals of the battery and configuring the charger to operate in a first constant voltage mode when the voltage across the two terminals of the battery is equal to a first termination voltage;
in the first constant voltage mode, monitoring a current flowing through the battery and configuring the charger to operate in a second constant current mode when the current flowing through the battery is equal to a first termination current, wherein the first termination current is a fraction of the current flowing through the battery in the first constant current mode;
in the second constant current mode, monitoring the voltage across two terminals of the battery and configuring the charger to operate in a second constant voltage mode when the voltage across the two terminals of the battery is equal to a second termination voltage; and
in the second constant voltage mode, monitoring the current flowing through the battery and configuring the charger to operate in a third constant current mode when the current flowing through the battery is equal to a second termination current, wherein the second termination current is a fraction of the current flowing through the battery in the second constant current mode.

11. The method of claim 10, further comprising:
in the first constant current mode, charging the battery with a 3C rate;
in the second constant current mode, charging the battery with a 2C rate; and
in the third constant current mode, charging the battery with a 1C rate.

12. The method of claim 10, further comprising:
in the first constant voltage mode, regulating the voltage across two terminals of the battery equal to the first termination voltage; and
in the second constant voltage mode, regulating the voltage across two terminals of the battery equal to the second termination voltage.

13. The method of claim 10, further comprising:
in the first constant voltage mode, configuring the charger such that an output voltage of the charger drops in a linear manner to compensate an internal resistance (IR) drop of the battery.

14. The method of claim 10, further comprising:
the first termination voltage is approximately equal to 3.8 V; and
the second termination voltage is approximately equal to 4.2 V.

15. The method of claim 10, further comprising:
in the third constant current mode, monitoring the voltage across two terminals of the battery and configuring the charger to operate in a third constant voltage mode when the voltage across the two terminals of the battery is equal to a third termination voltage, wherein the third termination voltage is approximately equal to 4.4 V.

16. An apparatus comprising:
a charger configured to apply a charge current to a battery; and
a controller configured to monitor a voltage across two terminals of the battery and a current flowing through the battery, wherein, based on the voltage across two terminals of the battery and the current flowing through the battery, the controller configures the charger to operate in a plurality of constant current modes and a plurality of constant voltage modes, and wherein the plurality of constant current modes and the plurality of constant voltage modes are applied to the charger consecutively, and wherein the plurality of constant current modes and the plurality of constant voltage modes form a plurality of charging steps, each charging step comprising four parameters including a termination voltage, a charge current, a termination current and a time-out, and wherein a behavior of each charging step is determined by the four parameters.

17. The apparatus of claim 16, wherein:
in a first constant current mode, the charger is configured to leave the first constant current mode and enter a first constant voltage mode after the controller detects the voltage across the two terminals of the battery is equal to a first termination voltage; and
in the first constant voltage mode, the charger is configured to leave the first constant voltage mode and enter a second constant current mode after the controller detects the current flowing through the battery is equal to a first termination current.

18. The apparatus of claim 17, wherein:
the first termination current is a fraction of the current flowing through the battery in the first constant current mode.

19. The apparatus of claim 17, wherein:
the charger is configured to leave a first charging step and enter a second charging step in an autonomous manner.

20. The apparatus of claim 17, wherein:
the voltage across the two terminals of the battery in the first constant voltage mode is equal to the first termination voltage.
